(19) United States
(12) Patent Application Publication
(10) Pub. No.: US 2011/0095396 A1
(43) Pub. Date: Apr. 28, 2011

(54) METHOD AND STRUCTURE FOR SILICON NANOCRYSTAL CAPACITOR DEVICES FOR INTEGRATED CIRCUITS

(75) Inventor: MIENO FUMITAKE, Shanghai (CN)

(73) Assignee: Semiconductor Manufacturing International (Shanghai) Corporation, Shanghai (CN)

(21) Appl. No.: 12/887,481

(22) Filed: Sep. 21, 2010

(30) Foreign Application Priority Data
Oct. 23, 2009 (CN) 200910197614.2

(51) Int. Cl. H01L 27/08; H01L 21/02

(52) U.S. Cl. 257/532; 438/396; 438/386; 257/E27.048; 257/E21.008; 257/E21.396

(57) ABSTRACT

An improved semiconductor device, including a capacitor structure. The device has a first electrode member, which has a first length and a first width. The device also has a second electrode member, which has a second length and a second width. Additionally, the device includes a capacitor dielectric material provided between the first electrode member and the second electrode member according to a specific embodiment. Depending upon the embodiment, the capacitor dielectric material is made of a suitable material or materials such as Al₂O₃, HfO₂, SiN, NO, Al₂O₃/HfO₂, AlN_{y}Oₓ, ZrO₂, any combinations of these, and the like. The device further includes a plurality of silicon nanocrystals spatially disposed in an area associated with the first width and the first length of the first electrode member. Each one of the nanocrystals has a size of about 20 nanometers and less according to a specific embodiment.

### CROSS-REFERENCES TO RELATED APPLICATIONS

This application claims priority to Chinese Application No. 200910197614.2, filed on Oct. 23, 2009, commonly assigned herewith and incorporated in its entirety by reference herein for all purposes.

### BACKGROUND OF THE INVENTION

The present invention is directed to integrated circuits and their processing for the manufacture of semiconductor devices. More particularly, the invention provides a method and device for manufacturing a stack capacitor of a dynamic random access memory device, commonly called DRAMs, but it would be recognized that the invention has a much broader range of applicability. For example, the invention can be applied to other devices having stack capacitor designs and/or like structures.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. Additionally, as devices require faster and faster designs, process limitations exist with certain conventional processes and materials.

An example of such a process is the manufacture of capacitor structure for memory devices. Such capacitor structures include, among others, trench capacitor, and stack capacitor designs. Although there have been significant improvements, such designs still have many limitations. As merely an example, these designs must become smaller and smaller but still require large voltage storage requirements. Additionally, these capacitor designs are often difficult to manufacture and generally require complex manufacturing processes and structures, which lead to inefficiencies and may cause low yields. Examples of such capacitor designs are illustrated in FIG. 1. As shown, FIG. 1 illustrates a stack and/or trench design 100 and a design using rugged or hemispherical grained silicon bearing particles 103. Rugged or hemispherical grained silicon particles often have a dimension of about 2-20 nm per particle on an average. These and other limitations will be described in further detail throughout the present specification and more particularly below.

From the above, it is seen that an improved technique for processing semiconductor devices is desired.

### BRIEF SUMMARY OF THE INVENTION

According to the present invention, techniques for processing integrated circuits for the manufacture of semiconductor devices are provided. More particularly, the invention provides a method and device for manufacturing a stack capacitor of a dynamic random access memory device, commonly called DRAMs, but it would be recognized that the invention has a much broader range of applicability. For example, the invention can be applied to other devices having stack capacitor designs and/or like structures.

In a specific embodiment, the present invention provides a semiconductor device, including a capacitor structure, e.g., stack capacitor, trench capacitor, or other like structure physically and/or functionally. The device has a first electrode member (e.g., doped polysilicon, combinations of conductive materials, metals), which has a first length and a first width. The device also has a second electrode member (e.g., doped polysilicon, combinations of conductive materials, metals) coupled to the first electrode member, which has a second length and a second width. A capacitor dielectric material is provided between the first electrode member and the second electrode member according to a specific embodiment. Depending upon the embodiment, the capacitor dielectric is made of a suitable material or materials such as Al₂O₃, HfO₂, silicon nitride, silicon oxynitride, ONO (silicon oxide on silicon nitride on silicon oxide) stack, Al₂O₃/HfO₂, AlN_{y}Oₓ, ZrO₂, any combinations of these, and the like. These materials can be deposited using ALD, MOCVD, UHV-PVD, reactive sputtering and/or chemical solution according to a specific embodiment. The device includes a plurality silicon nanocrystals spatially disposed in an area associated with the first width and the first length of the first electrode member. Each one of the silicon nanocrystals has a size of about 20 nanometers and less according to a specific embodiment. In other embodiments, the nanocrystals can have an average size of about 2 nanometers and less, but can be other dimensions as well.

In an alternative specific embodiment, the present invention provides a method for fabricating semiconductor devices. The method includes providing a semiconductor substrate, e.g., silicon wafer. The method includes forming a first electrode member coupled to the semiconductor substrate. The first electrode member has a first length and a first width according to a specific embodiment. The method includes forming a first capacitor dielectric material overlying the first electrode member. Depending upon the embodiment, the capacitor dielectric material is made of a suitable material or materials such as Al₂O₃, HfO₂, silicon nitride, silicon oxynitride, ONO (silicon oxide on silicon nitride on silicon oxide) stack, Al₂O₃/HfO₂, AlN_{y}Oₓ, ZrO₂, any combinations of these, and the like. These materials can be deposited using ALD, MOCVD, UHV-PVD, reactive sputtering and/or chemical solution according to a specific embodiment. The method includes depositing a plurality of silicon nanocrystals spatially disposed in an area associated with the first width and the first length of the first electrode member. The one or more of the nanocrystals have a size of about 20 nanometers and less according to a specific embodiment. The method also forms a second capacitor dielectric material overlying the plurality of silicon nanocrystals and exposed portions of the first capacitor dielectric material. The method includes forming a second electrode member overlying the second capacitor dielectric material.

Many benefits are achieved by way of the present invention over conventional techniques. For example, the present technique provides an easy to use process that relies upon conventional technology. In some embodiments, the method provides higher device yields in dies per wafer. Additionally, the method provides a process that is compatible with conventional process technology without substantial modifications to conventional equipment and processes. Preferably, the invention provides for an improved capacitor structure using silicon nanocrystals for improved capacitance used for dynamic random access memory devices. Preferably, the nanocrystals can be used in certain smaller dimension structures without short circuit, and/or other undesirable results according to the preferred embodiment. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram of conventional capacitor structures;

FIGS. 2 through 6 are simplified diagrams illustrating a method for forming a capacitor structure according to embodiments of the present invention; and

FIG. 7 is a simplified diagram of experimental data using the present method and structure according to an embodiment of the present invention

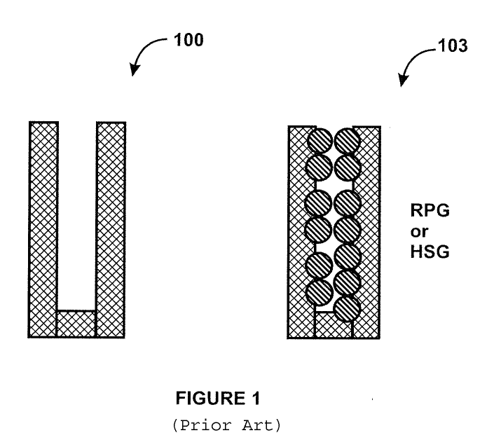

### DETAILED DESCRIPTION OF THE INVENTION

According to the present invention, techniques for processing integrated circuits for the manufacture of semiconductor devices are provided. More particularly, the invention provides a method and device for manufacturing a stack capacitor of a dynamic random access memory device, commonly called DRAMs, but it would be recognized that the invention has a much broader range of applicability. For example, the invention can be applied to other devices having stack capacitor designs and/or like structures.

A method for manufacturing a capacitor device according to an embodiment of the present invention may be outlined as follows.

1. Provide a semiconductor substrate, e.g., silicon wafer;

2. Form a plurality of transistor structures overlying the substrate;

3. Form a first electrode member coupled to one of the transistor structures on the semiconductor substrate, the first electrode member having a first length and a first width;

4. Form a first a capacitor dielectric material overlying the first electrode member;

5. Deposit a plurality silicon nanocrystals spatially disposed in an area associated with the first width and the first length of the first electrode member;

6. Form a second capacitor dielectric material overlying the plurality of silicon nanocrystals and exposed portions of the first capacitor dielectric material;

7. Form a second electrode member overlying the second capacitor dielectric material; and

8. Perform other steps, as desired.

The above sequence of steps provides a method according to an embodiment of the present invention. As shown, the method uses a combination of steps including a way of forming one or more films of materials using nanocrystal silicon bearing material for a capacitor device structure. Other alternatives can also be provided where steps are added, one or more steps are removed, or one or more steps are provided in a different sequence without departing from the scope of the claims herein. Details of the present method and structure can be found throughout the present specification and more particularly below.

An alternative method for manufacturing a capacitor device for a dynamic random access memory device according to an embodiment of the present invention may be outlined as follows.

1. Provide a semiconductor substrate, e.g., silicon wafer;

2. Form a plurality of transistor structures overlying the substrate;

3. Form a first electrode member coupled to one of the transistor structures on the semiconductor substrate, the first electrode member having a first width and a first length;

4. Form a first capacitor dielectric material overlying the first electrode member;

5. Deposit a plurality silicon nanocrystals spatially disposed in an area associated with the first width and the first length of the first electrode member;

6. Form a second capacitor dielectric material overlying the plurality of silicon nanocrystals and exposed portions of the first capacitor dielectric material;

7. Form a second electrode member overlying the second capacitor dielectric material; and

8. Perform other steps, as desired.

The above sequence of steps provides a method according to an embodiment of the present invention. As shown, the method uses a combination of steps including a way of forming one or more films of materials using nanocrystal silicon bearing material for a capacitor device structure, which may be for a trench or stack type capacitor design, depending upon the specific embodiment. Other alternatives can also be provided where steps are added, one or more steps are removed, or one or more steps are provided in a different sequence without departing from the scope of the claims herein. Details of the present method and structure can be found throughout the present specification and more particularly below.

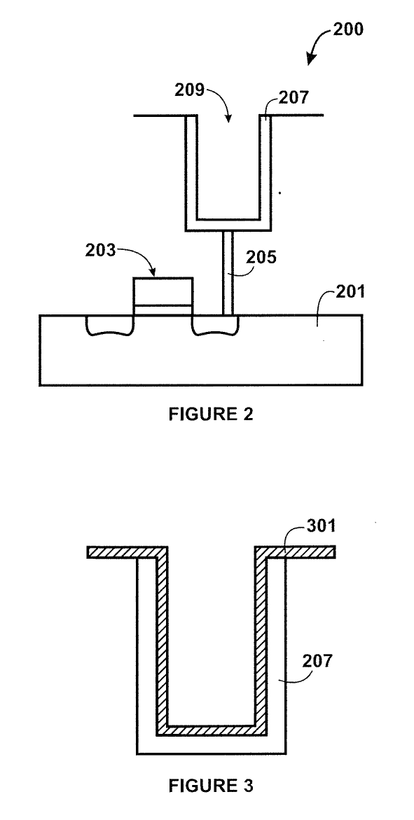

FIGS. 2 through 6 are simplified diagrams illustrating a method for forming a capacitor structure according to embodiments of the present invention. These diagrams are merely examples, which should not unduly limit the scope of the claims herein. One of ordinary skill in the art would recognize many variations, modifications, and alternatives. As shown is a method for fabricating semiconductor devices. The method includes providing a semiconductor substrate 201, e.g., silicon wafer, which is on a partially completed device structure 200. The substrate includes a plurality of MOS devices 203 thereon, including source and drain regions, which couple via plug structure 205, to a capacitor structure.

In a preferred embodiment, the method includes forming a first electrode member 207 coupled to the semiconductor substrate. The first electrode member has a first length and a first width according to a specific embodiment. The first electrode member is initially provided as an amorphous silicon material, which is deposited at a temperature of less than 525 degrees Celsius. In a preferred embodiment, the amorphous silicon material is doped using an impurity such as phosphorous or the like. The amorphous silicon material is often blanket deposited and subject to chemical mechanical polishing or the like.

As shown, the amorphous silicon material is deposited in a container or trench structure 209, which is formed out of an interlayer dielectric material. The interlayer dielectric material can be a single layer or multiple layers depending upon the specific embodiment. The interlayer dielectric material can be a borophosphosilicate glass, a phosphosilicate glass, a fluorinated glass, an undoped glass, or any combination of these materials and the like. Of course, one of ordinary skill in the art would recognize other variations, modifications, and alternatives.

The method includes forming a first capacitor dielectric material 301 overlying the first electrode member. Depending upon the embodiment, the capacitor dielectric is made of a suitable material or materials such as aluminum oxide (Al₂O₃), hafnium oxide (HfO₂), silicon nitride, silicon oxynitride, ONO (silicon oxide on silicon nitride on silicon oxide) stack, Al₂O₃/HfO₂, AlN_{y}Oₓ, ZrO₂, any combinations of these, and the like. These materials can be deposited using ALD, MOCVD, UHV-PVD, reactive sputtering and/or chemical solution according to a specific embodiment. In a preferred embodiment, the dielectric material is Al₂O₃ and is deposited to a thickness ranging from about 2 nm to about 10 nm using techniques such as ALD. Of course, there can be other variations, modifications, and alternatives.

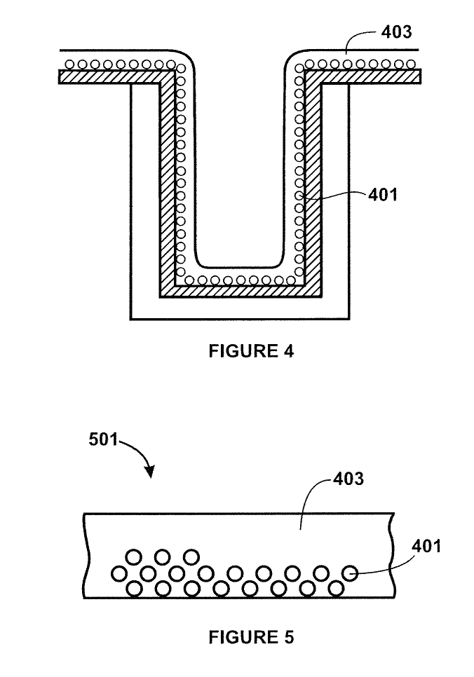

Referring now to FIG. 4, the method includes depositing a plurality of silicon nanocrystals 401 spatially disposed in an area associated with the first width and the first length of the first electrode member. Each of the plurality of silicon nanocrystals has a size of about 2 nanometers and less according to a specific embodiment. In other embodiments, each of the plurality of silicon nanocrystals can have a size of about 20 nanometers and less. In a specific embodiment, the nanocrystals can be formed using a silane gas (e.g., SiH₄) provided at about 2 to 5 standard cubic centimeters per minute (SCCM). The silane gas may be provided with a carrier gas including helium, argon, or the like. The carrier gas is provided at about 1 to 2 SCCM according to a specific embodiment. Depending upon the embodiment, the pressure is maintained at about 0.2 Torr or ranges from about 0.1 Torr to 1 Torr. The temperature is also provided at about 550 degrees Celsius to about 580 degrees Celsius according to a specific embodiment. Additionally, the silicon nanocrystals are provided overlying at least the capacitor dielectric material of the capacitor structure having a width of about 20 nm to about 40 nm in a specific embodiment. Of course, there can be other variations, modifications, and alternatives.

In a specific embodiment, the method also forms a second capacitor dielectric material 403 overlying the plurality of silicon nanocrystals and exposed portions of the first capacitor dielectric material. Depending upon the embodiment, the capacitor dielectric is made of a suitable material or materials such as aluminum oxide (Al₂O₃), hafnium oxide (HfO₂), silicon nitride, silicon oxynitride, ONO (silicon oxide on silicon nitride on silicon oxide) stack, Al₂O₃/HfO₂, AlN_{y}Oₓ, ZrO₂, any combinations of these, and the like. These materials can be deposited using ALD, MOCVD, UHV-PVD, reactive sputtering and/or chemical solution according to a specific embodiment. In a preferred embodiment, the dielectric material is Al₂O₃ and is deposited to a thickness ranging from about 1 nm to about 5 nm and preferably less than 2 nm. Of course, there can be other variations, modifications, and alternatives.

FIG. 5 is a simplified diagram illustrating a capacitor dielectric stack 501 according to an embodiment of the present invention. As shown, the capacity dielectric stack includes first dielectric layer 301, a plurality of silicon nanocrystals 401, and second dielectric layer 403, which have been described in sections above. As shown, the plurality of silicon nanocrystals are provided within a volume of the capacitor dielectric material and in contact with the first electrode member in a specific embodiment. Of course there can be other variations, modifications, and alternatives.

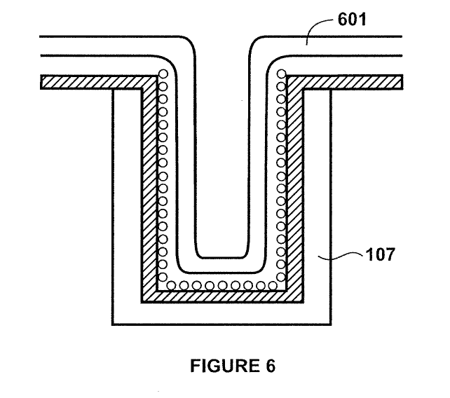

Referring to FIG. 6, the method includes forming a second electrode member 601 overlying the second capacitor dielectric material. The first electrode member is initially provided as an amorphous silicon material, which is deposited at a temperature of less than 525 degrees Celsius. In a preferred embodiment, the amorphous silicon material is doped using an impurity such as phosphorus or the like. The amorphous silicon material is often blanket deposited and subject to chemical mechanical polishing or the like. Of course, there can be other variations, modifications, and alternatives.

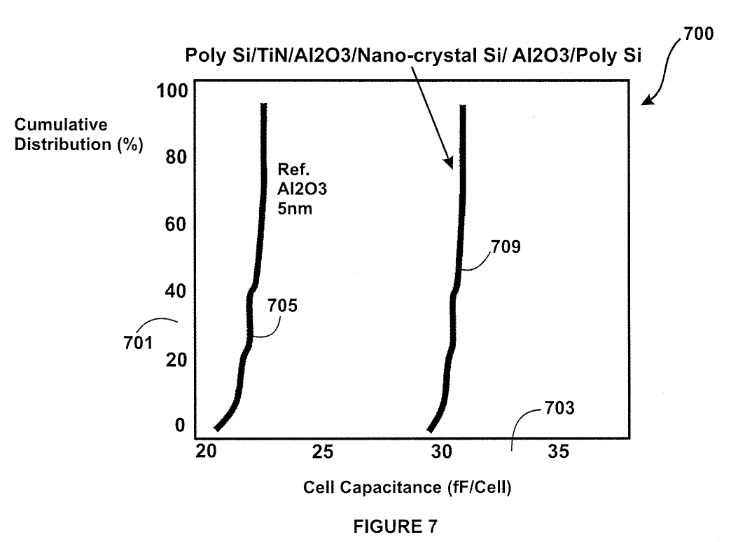

FIG. 7 is a simplified diagram of experimental data 700 using the present method and structure according to an embodiment of the present invention. This diagram is merely an example, which should not unduly limit the scope of the claims herein. One of ordinary skill in the art would recognize many variations, modifications, and alternatives. As shown, the vertical axis 701 represents a cumulative distribution of materials and the horizontal axis 703 represents cell capacitance in fempto farads per cell. A reference plot 705 for a capacitor dielectric consisting of Al₂O₃ is shown. As shown, the Al₂O₃ reference plot has a capacitance ranging from about 20 fF/cell. A capacitor dielectric 709 including the silicon nanocrystals is also shown. The silicon nanocrystal enhanced dielectric has a cell capacitance of about 30 fF/cell, which is much larger than the conventional Al₂O₃ based structure. The present capacitor structure includes polysilicon electrodes, an overlying titanium nitride bearing material, and a dielectric material including Al₂O₂ and silicon nanocrystals. The present structure is also for a 0.13 micron technology node for a memory device. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A semiconductor device comprising:
a first electrode member, the first electrode member having a first length and a first width;
a second electrode member coupled to the first electrode member, the second electrode member having a second length and a second width;
a capacitor dielectric material provided between the first electrode member and the second electrode member; and
a plurality of silicon nanocrystals spatially disposed in an area associated with the first width and the first length of the first electrode member, one or more of the silicon nanocrystals having a size of about 20 nanometers and less.

2. The device of claim 1, wherein the size is about 10 nanometers and less.

3. The device of claim 1, wherein the size is about 2 nanometers and less.

4. The device of claim 1, wherein the first electrode member and the second electrode member comprise a polysilicon material.

5. The device of claim 1, wherein the capacitor dielectric material comprises Al₂O₃.

6. The device of claim 1, wherein the capacitor dielectric material comprises HfO₂.

7. The device of claim 1, wherein the capacitor dielectric material comprises silicon nitride.

8. The device of claim 1, wherein the capacitor dielectric material comprises an ONO stack.

9. The device of claim 1, wherein the capacitor dielectric material comprises Al₂O₃ and HfO₂.

10. The device of claim 1, wherein the first electrode member, the capacitor dielectric material, and the second electrode member form a stack capacitor for a dynamic random access memory device.

11. The device of claim 1, wherein the first electrode member, the capacitor dielectric material, and the second electrode member form a trench capacitor for a dynamic random access memory device.

12. The device of claim 1, wherein the plurality of silicon nanocrystals cause an increase in capacitance between the first electrode member and the second electrode member.

13. The device of claim 1, wherein the first electrode member, the capacitor dielectric, the silicon nanocrystals, and the second capacitor member form a capacitor having a capacitance of about 30 fF per cell and greater.

14. The device of claim 1, wherein the plurality of silicon nanocrystals are provided on and in contact with the first electrode member.

15. The device of claim 1, wherein the plurality of silicon nanocrystals are provided entirely within a volume of the capacitor dielectric material.

16. A method for fabricating semiconductor devices comprising:
providing a semiconductor substrate;
forming a first electrode member coupled to the semiconductor substrate, the first electrode member having a first length and a first width;
forming a first capacitor dielectric material overlying the first electrode member;
depositing a plurality of silicon nanocrystals spatially disposed in an area associated with the first width and the first length of the first electrode member, one or more of the nanocrystals having a size of about 20 nanometers and less;
forming a second capacitor dielectric material overlying the plurality of silicon nanocrystals and exposed portions of the first capacitor dielectric material; and
forming a second electrode member overlying the second capacitor dielectric material.

17. The method of claim 16, wherein the size is about 10 nanometers and less.

18. The method of claim 16, wherein the size is about 2 nanometers and less.

19. The method of claim 16, wherein the first electrode member and the second electrode member comprise a polysilicon material.

20. The method of claim 16, wherein the first and the second capacitor dielectric materials comprise Al₂O₃.

21. The method of claim 16, wherein the first and the second capacitor dielectric materials comprise HfO₂.

22. The method of claim 16, wherein the first and the second capacitor dielectric materials comprise SiN.

23. The method of claim 16, wherein the first and the second capacitor dielectric materials comprise nitrogen oxide.

24. The method of claim 16, wherein the first and the second capacitor dielectric material comprises Al₂O₃ and HfO₂.

25. The method of claim 16, wherein the first electrode member, the first and the second capacitor dielectric materials, and the second electrode member form a stack capacitor for a dynamic random access memory device.

26. The method of claim 16, wherein the first electrode member, the first and the second capacitor dielectric materials, and the second electrode member form a trench capacitor for a dynamic random access memory device.

27. The method of claim 16, wherein the plurality of silicon nanocrystals cause an increase in capacitance from a first determined value to a second determined value between the first electrode member and the second electrode member.

28. The method of claim 16, wherein the first electrode member, the first and the second capacitor dielectric materials, the silicon nanocrystals, and the second capacitor member form a capacitor having a capacitance of about 30 fF/cell and greater.

29. The method of claim 16, wherein the plurality of silicon nanocrystals are provided entirely within a volume of the first and the second capacitor dielectric materials.
